(19) United States
(12) Patent Application Publication
(10) Pub. No.: US 2008/0174357 A1
(43) Pub. Date: Jul. 24, 2008

(54) SEMICONDUCTOR DEVICE

(75) Inventor: Hajime MATSUDA, Yamanashi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: EUDYNA DEVICES INC., Nakakoma-gun (JP)

(21) Appl. No.: 12/018,420

(22) Filed: Jan. 23, 2008

(30) Foreign Application Priority Data
Jan. 23, 2007 (JP) 2007-012156

(51) Int. Cl. H03K 17/687

(52) U.S. Cl. 327/427

(57) ABSTRACT

A semiconductor device having a switch includes a first FET connected to a terminal and a second FET of a stage following that of the first FET. The gate width of the first FET is greater than that of the second FET. A sum of lengths of a source electrode and a drain electrode of the first FET in a direction perpendicular to the gate width of the first FET is smaller than a sum of lengths of a source electrode and a drain electrode of the second FET in a direction perpendicular to the gate width of the second FET.

The present application is based on Japanese Patent Application No. 2007-012156 filed Jan. 23, 2007, the entire disclosure of which is hereby incorporated by reference.

### BACKGROUND OF THE INVENTION

1. Field of the Invention

The present invention relates to semiconductor devices, and more particularly, to a semiconductor device having a plurality of FETs that switch a high-frequency signal.

2. Description of the Related Art

Recently, an RF (Radio Frequency) switch formed by field effect transistors (FETs) has been used for cellular phones that handle RF (high frequency) signals. Japanese Patent Application Publication No. 2005-348206 discloses a switch in which a plurality of FETs are connected in series between two input/output terminals. FIG. 6 of the above publication shows a structure designed to prevent the FETs from being turned ON when a high-power signal is applied to the switch that is in the OFF state. In the proposed structure, the FETs among the plurality of FETs that are directly connected to the input/output terminals have comparatively wide gates in order to increase capacitances relatively.

The greatest amplitude of the input signal is applied to the FET of the initial stage among the FETs that form the switch. The increased gate width of the FET of the initial stage improves the linearity in the ON state, but degrades the cutoff characteristic in the OFF state.

### SUMMARY OF THE INVENTION

The present invention has been made in view of the above circumstances and provides a semiconductor device capable of securing linearity in the ON state and restraining the cutoff characteristic in the OFF state from being degraded.

According to an aspect of the present invention, there is provided a semiconductor device having a switch including: a terminal; another terminal; a first FET connected to the terminal; and a second FET of a stage following that of the first FET, a gate width of the first FET being greater than that of the second FET, a sum of lengths of a source electrode and a drain electrode of the first FET in a direction perpendicular to the gate width of the first FET being smaller than a sum of lengths of a source electrode and a drain electrode of the second FET in a direction perpendicular to the gate width of the second FET.

According to another aspect of the present invention, there is provided a semiconductor device including: switches connected to a common terminal, at least one of the switches including: a first FET connected to a terminal; and a second FET of a stage following that of the first FET, a gate width of the first. FET being greater than that of the second FET, a sum of lengths of a source electrode and a drain electrode of the first FET in a direction perpendicular to the gate width of the first FET being smaller than a sum of lengths of a source electrode and a drain electrode of the second FET in a direction perpendicular to the gate width of the second FET.

### BRIEF DESCRIPTION OF THE DRAWINGS

FIG. 1 is a circuit diagram of an SPDT switch circuit;

FIG. 2 is an equivalent circuit diagram of the SPDT switch circuit;

FIGS. 3A and 3B are graphs of drain current vs. drain voltage characteristics of FETs that form a switch;

FIGS. 4A and 4B are equivalent circuit diagrams of FETs that form a switch;

FIG. 5 is a graph of an ON-state resistance and an OFF-state capacitance as a function of an electrode length of an FET;

FIG. 6A is a plan view of an FET of an initial stage of a switch in accordance with a first embodiment;

FIG. 6B is a plan view of an FET of an intermediate stage of the switch in accordance with the first embodiment;

FIGS. 7A and 7B show exemplary single-finger FETs;

FIG. 8 is a block diagram of a switch circuit in accordance with a second embodiment;

FIG. 9 is a block diagram of an SP6T in accordance with the second embodiment; and

FIG. 10 is a circuit diagram of a switch employed in the second embodiment.

### DESCRIPTION OF THE PREFERRED EMBODIMENTS

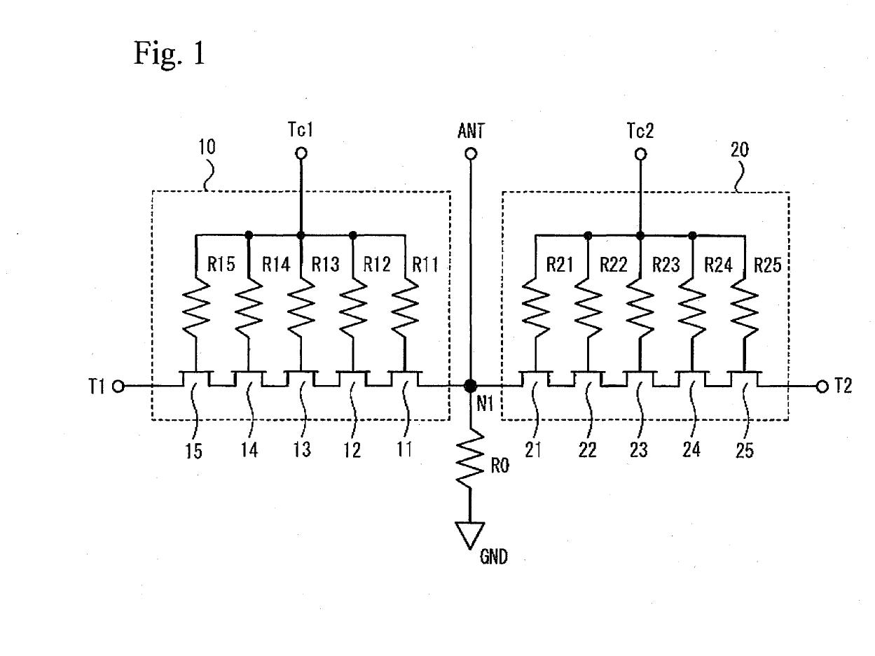

Now, a description will be given of the principles of the present invention. FIG. 1 is a circuit diagram of an SPDT (Single Pole Double Throw) switch circuit using FETs.

Referring to FIG. 1, two switches 10 and 20 are connected to an antenna terminal ANT. A node N1 is grounded via a resistor R0. At the node N1, the two switches 10 and 20 and the antenna terminal ANT are connected. The switch 10 has FETs 11 through 15 and resistors R11 through R15. The FETs 11 through 15 are connected in series between a terminal T1 and the node N1 so that the source and the drain of the adjacent FETs are connected. A control terminal Tc1 is coupled to gates of the FETs 11 through 15 via the resistors R11 through T15, respectively. The switch 20 includes FETs 21 through 25 and resistors R21 through R25, and is connected to the node N1, a terminal T2 and a control terminal Tc2.

The switch circuit shown in FIG. 1 operates in response to control voltages applied to the control terminals Tc1 and Tc2 so that the FETs 11 through 15 of the switch 10 and the FETs 21 through 25 of the switch 20 are turned ON and OFF. That is, the switch circuit switches a high-frequency (RF) signal applied to the switches 10 and 20 via the antenna terminal ANT. For example, when a positive voltage is applied to the control terminal Tc2, forward current flows through the gates of the FETs 21 through 25, and the node N1 has a positive potential defined by the resistor R0 and the gate forward currents of the FETs 21 through 25. In this case, the gates of the FETs 21 through 25 have a positive potential with respect to the node N1, and the FETs 21 through 25 are turned ON. On the other hand, the control terminal Tc1 is supplied with a voltage that turns OFF the FETs 11 through 15. That is, a negative voltage with respect to the node N1 is applied to the control terminal Tc1. In this manner, one of the switches 10 and 20 are turned ON, and the other is turned OFF, so that the high-frequency signal is allowed to pass through one of the switches that is ON, and is blocked by the other switch that is OFF.

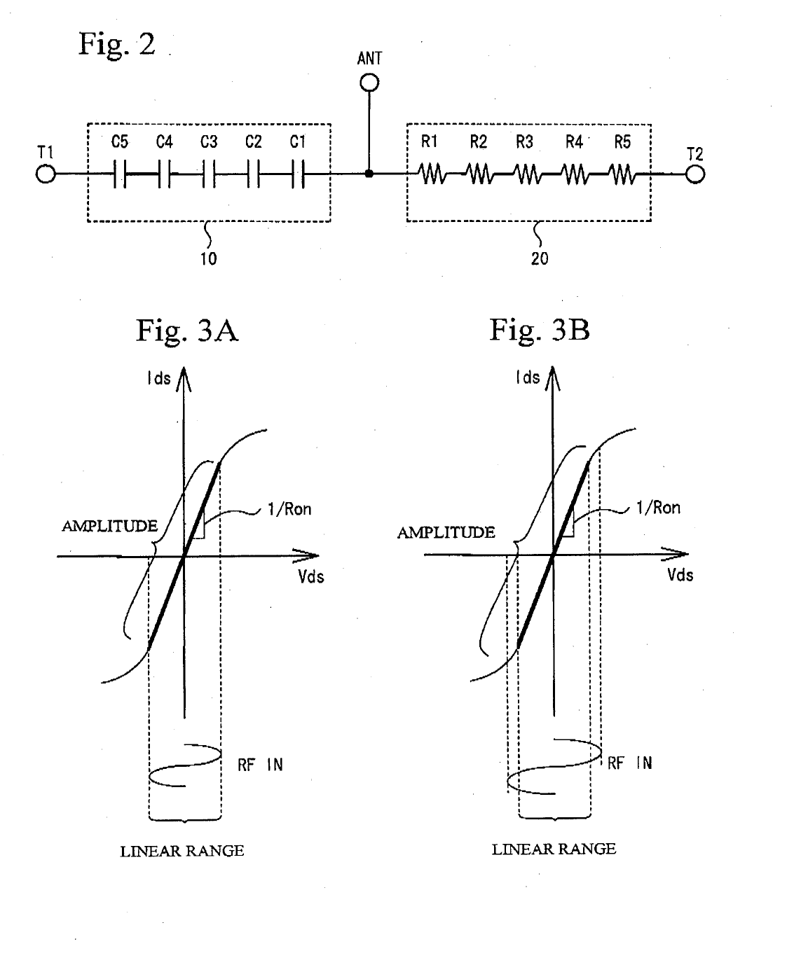

FIG. 2 is an equivalent circuit of the switch circuit shown in FIG. 1 in which the switch 10 is in the OFF state and the switch 20 is in the ON state. Referring to FIG. 2, the FETs 11 through 15 of the switch 10 are equivalently represented as capacitors C1 through C5, respectively. The FETs 21 through 25 of the switch 20 are equivalently represented as resistors R1 through R5, respectively. The total capacitance of the capacitors C1 through CS is an OFF-state capacitance Coff, and the total resistance of the resistors R1 through R5 is an ON-state resistance Ron.

FIG. 3A is a graph of a drain current vs. drain voltage characteristic of the FETs 22 through 25 of intermediate stages of the switch 20 that is in the ON state. A range indicated by a thick line is a linear range in which the drain current Ids is proportional to the drain voltage Vds with an inclination of 1/Ron. The amplitude of the high-frequency signal is within the linear range. FIG. 3B is a graph of a drain current vs. drain voltage characteristic of the FET 21 to which the high-frequency signal is applied first. The high-frequency signal is serially applied to the FETs 21 through 25 in this order. The high-frequency signal is attenuated by an amount equal to the ON-state resistance each time it passes through one FET. The FET closer to the input terminal to which the high-frequency signal is applied receives the greater amplitude thereof. Thus, the high-frequency signal of power higher than that applied to the FETs of the intermediate stages shown in FIG. 3A is applied to the FET 21 of the initial stage. As shown in FIG. 3B, the amplitude of the high-frequency signal exceeds the linear range at the FET 21 of the initial stage. Thus, the linearity is degraded and distortion is increased.

Taking the above into consideration, the gate width of the FET 21 to which the high-frequency signal having a comparatively great amplitude is made greater than gate widths of the FETs 22 through 25. With this structure, it is possible to restrain the linearity of the FET 21 from being degraded. However, the inventors found out that the above structure degrades the cutoff characteristic in the OFF state of the switch 20, More specifically, the increased gate width of the FET 21 increases the total area of the source electrode and the drain electrode. This increases the source-drain capacitance (Cds) of the FET 21. The FET 21 having a large Cds has small impedance between the source and the drain, which degrades the cutoff characteristic.

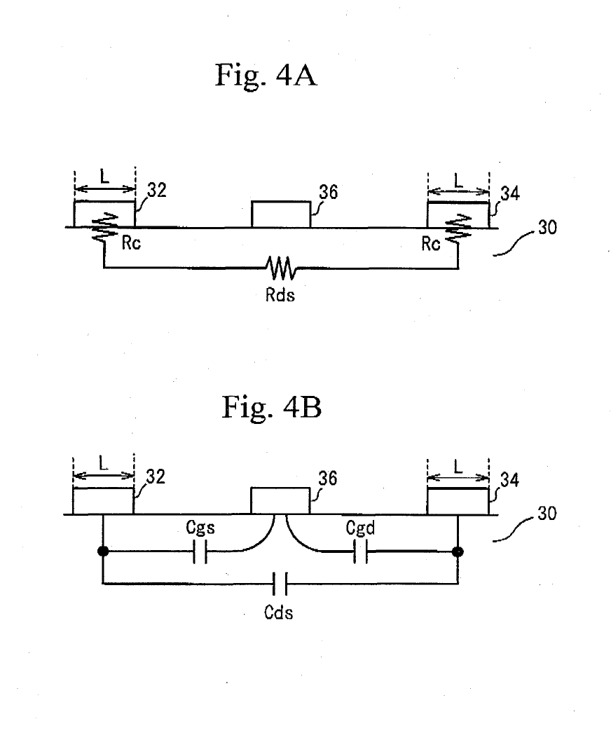

FIG. 4A is an equivalent circuit diagram of the ON-state resistance Ron of FET. There are provided a source electrode 32, a drain electrode 34 and a gate electrode 36 on a semiconductor layer 30. The source electrode 32 and the drain electrode 34 have an electrode length L. It is assumed that the contact resistance between the source electrode 32 or the drain electrode 34 and the semiconductor layer 30 is Rc, and the resistance of the semiconductor layer 30 between the source electrode 32 and the drain electrode 34 is Rds. The ON-state resistance Ron is expressed as follows:

Ron=Rds+2Rc (1)

FIG. 4B is an equivalent circuit diagram of the OFF-state capacitance Coff of FET. The source electrode 32, the drain electrode 34 and the gate electrode 36 are provided on the semiconductor layer 30. It is assumed that the capacitance between the source electrode 32 and the drain electrode 34 is Cds, the capacitance between the source electrode 32 and the gate electrode 36 is Cgs, and the capacitance between the drain electrode 34 an the gate electrode 36 is Cgd. The OFF-state capacitance Coff is expressed as follows:

Coff=[(Cgs·Cgd)/(Cgs+Cgd)]+Cds (2)

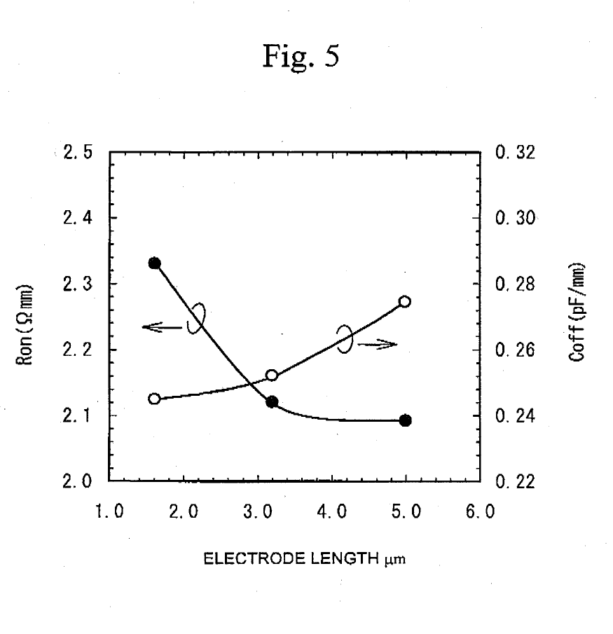

FIG. 5 is a graph showing measurement results of the ON-state resistance Ron and the OFF-state capacitance Coff as a function of the electrode length L of the source electrode 32 and the drain electrode 34 (the length in the direction perpendicular to the gate width). In the measurement, the OFF-state capacitance Coff is obtained by measuring Cgs, Cgd and Cds and inserting the measured values into expression (2). The FET used in the measurement is a HEMT (High Electron Mobility Transistor) having an electron supply layer of AlGaAs (aluminum gallium arsenide) and a channel layer of InGaAs (indium gallium arsenide).

FIG. 5 shows that the ON-state resistance Ron increases as the electrode length L decreases. In contrast, the OFF-state capacitance Coff increases the electrode length L increases. The OFF-state capacitance Coff can be reduced by reducing the electrode length L. The present invention has been made in view of the electrode length L dependence of the ON-state resistance and the OFF-state capacitance. The present invention is capable of restraining degradation of the cutoff characteristic in the OFF state. Now, exemplary embodiments of the present invention will be described.

### FIRST EMBODIMENT

A semiconductor device in accordance with a first embodiment has the FETs 11 through 15 of the switch 10 shown in FIG. 10 but has a modified arrangement in which FETs 11 and 15 (first FETs) have gate electrode lengths L and gate widths W different from those of the other FETs 12 through 14 (second FETs).

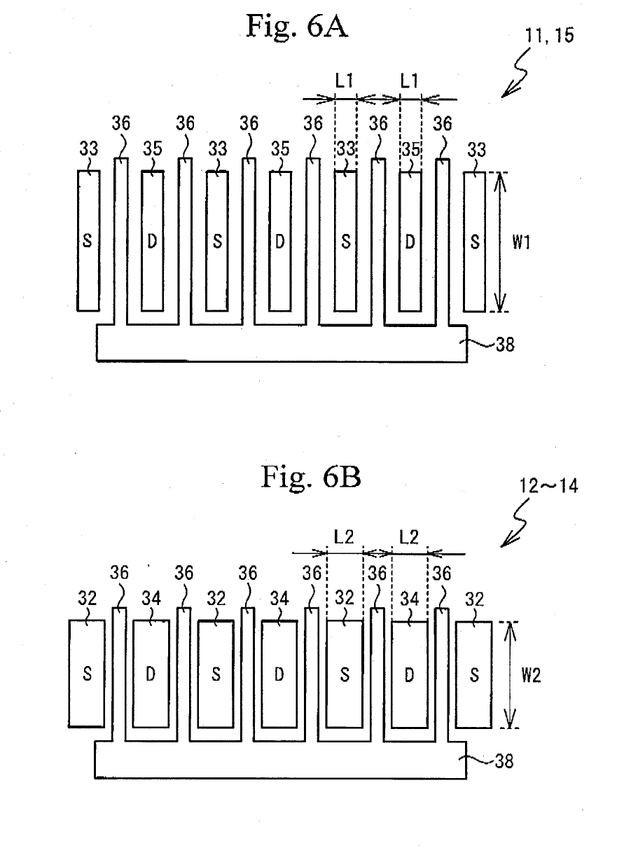

FIG. 6A is a plan view of the FETs 11 and 15. There is illustrated a multi-finger structure in which multiple source electrodes 33, multiple gate electrodes 36 and multiple drain electrodes 35 are arranged. All the gate electrodes 36 are connected to a gate bus bar 38. L1 denotes the electrode lengths of the source electrodes 33 and the drain electrodes 35, and W1 denotes the gate width per finger.

FIG. 6B is a plan view of the FETs 12 through 14. The source electrodes 32 and the drain electrodes 34 have electrode lengths L2 greater than the electrode lengths L1 of the source electrodes 33 and the drain electrodes 35 shown in FIG. 6A. The gate width W2 per finger is smaller than W1 shown in FIG. 6A.

It is assumed that the electrode lengths L of the FETs 11 and 15 are 3.2 μm, and the total gate width (gate width W1×the number of gate fingers) is 3250 μm. In this assumption, the ON-state resistance and the OFF-state capacitance are calculated from the graph of FIG. 5 as follows:

Ron=2.12(Ωmm)/3.25(mm)=0.65 Ω.

Coff=0.252(pF/mm)×3.25(mm)=0.82 pF

It is assumed that the electrode lengths L2 of the FETs 12 through 14 is 5.0 μm, and the total gate width (gate width W2×the number of gate fingers) is 3000 μm. In this assumption, the ON-state resistance and the OFF-state capacitance are calculated from the graph of FIG. 5 as follows:

Ron=2.09(Ωmm)/3.0(mm)=0.70Ω.

Coff=0.274(pF/mm)×3.0(mm)=0.82pF

From the above, the FETs 11 and 15 have the OFF-state capacitance values equal to those of the FETs 12 through 14. In contrast, the ON-state resistance Ron can be reduced by approximately 6.4%.

In the first embodiment, as shown in FIG. 1, the switch 10 has the FETs 11 through is connected in series between the terminals, namely, the antenna terminal ANT and the terminal T1. As shown in FIGS. 6A and 6B, the gate widths W1 of the FETs 11 and 15 (first FETs) connected to the antenna terminal ANT and the terminal T1 are greater than the widths W2 of the FETs 12 through 14 (second FETs) of the intermediate stages. The sum (L1+L1) of the electrode lengths L1 (the length in the direction perpendicular to the gate width W1) of the source electrode 33 and the drain electrode 35 in each the FETs 11 and 15 is smaller than the sum (L2+L2) of the source electrode 32 and the drain electrode 34 in each of the FETs 12 through 14.

According to the first embodiment, as has been described with reference to FIGS. 3A and 3B, the gate widths of the FETs 11 and 15 are made greater than those of the FETs 12 through 14, whereby the ON-state resistances Ron of the FETs 11 and 15 of the initial stages to which greatest power is applied can be reduced and the linear range of the drain current vs. drain voltage characteristic can be enlarged. It is thus possible to restrain the non-linearity effects such as distortion. The FETs 12 through 14 of the intermediate stages are not supplied with power as much as that applied to the FETs 11 and 15 of the initial stages. Thus, the linear ranges of the FETs 12 through 14 are not required to be as wide as those of the FETs 11 and 15. The gates of the FETs 11 and 15 required to have wide linear ranges are made comparatively wide, and the gates of the FETs 12 through 14 not required to have linear ranges as wide as those of the FETs 11 and 15 are made comparatively narrow. It is thus possible to secure the linearity of the switch 10. Further, the FETs 12 through 14 of the intermediate stages can be downsized, and thus the chip size can be reduced.

The sum (L1+L1) of the electrode lengths L1 in each of the FETs 11 and 15 are made smaller than the sum (L2+L2) of the electrode lengths L2 in each of the FETs 12 through 14. The total area of the source electrode 33 and the drain electrode 35 of the FETs 11 and 15 per unit gate width is less than the total area of the FETS 12 through 14. Thus, the OFF-state capacitances of the FETs 11 and 15 per unit gate width can be made less than those of the FETs 12 through 14. It is thus possible to reduce the OFF-state capacitances of the FETs 11 and 15 of the initial stages that are supplied with the highest voltage and are required to have small OFF-state capacitances. Thus, the cutoff characteristic of the switch 10 can be improved. The insertion loss relates to the total ON-state resistance of the FETs 11 through 15. Thus, the FETs 12 through 14 of the intermediate stages not required to have reduction in the OFF capacitance as much as that in the FETs 11 and 15 of the initial stages are designed to have a comparatively large sum of the electrode lengths L2 and to thus reduce the ON resistances. It is thus possible to realize a reduced sum of the ON resistances of the FETs 11 through 15 and reduce the insertion loss of the switch 10.

In FIG. 6 of the aforementioned application publication, the arrangement in which the gate widths of the FETs 101, 104, 105 and 108 are greater than those of the other FETs is intended to increase the capacitances of the FETs in order to prevent the FETs from being turned ON by an large amplitude of the signal. Thus, the purpose of the above arrangement disclosed in the aforementioned application publication is quite different from that of the first embodiment. Further, according to the first embodiment, the cutoff characteristic can be improved by setting the electrode lengths L1 of the source electrodes 33 and the drain electrodes 35 of the FETs 11 and 15 smaller than the lengths L2 of the source electrodes 32 and the drain electrodes 34 of the FETs 12 through 14.

The gate widths of the FETs 11 and 15 may not be greater than those of the FETs 12 through 14. This arrangement does not have improvement in the distortion characteristic of the switch 10 as much as that obtained in the first embodiment. Of course, it is possible to achieve improvement in reduction of the OFF-state capacitances of the FETs 11 and 15 of the initial stages required to reduce the OFF-state capacitance and to achieve improvement in reduction of the ON-state resistances of the FETs 12 through 14 of the intermediate stages not required to have reduction in the OFF-state capacitance as much as that for the FETs 11 and 15.

When there is a possibility that high-frequency signals maybe applied to both the terminal T1 and the antenna terminal ANT (these terminals are two input/output terminals) of the switch 10, preferably, the FETs (first FETs) that should be designed to reduce the electrode lengths L1 and increase the gate widths W1 are the FETs 11 and 15 connected directly to the terminal T1 and the antennal terminal ANT, respectively.

When the high-frequency signal is applied to either one of the terminal T1 and the antenna terminal ANT, one of the two FETs of the initial stages is designed to have the reduced electrode length LI and the increased gate width W1. That is, at least one (first FET) of the two FETs connected to the input/output terminals (multiple terminals) should have the reduced electrode length L1 or the increased gate width W1.

In the first embodiment, the FETs 11 and 15 have the identical electrode lengths Li of the source electrodes 33 and the drain electrodes 35. Alternatively, the source electrodes 33 and the drain electrodes 35 may have different electrode lengths L1. Even in this alternative, the aforementioned effects of the first embodiment may be obtained by setting the total electrode length of the source electrodes 33 and the drain electrodes 35 smaller than that of the FETs 12 through 14. In order to obtain the advantages more greatly, it is preferable that the electrode lengths L1 of both the source electrode 33 and the drain electrode 35 in each of the FETs 11 and 15 are smaller than the electrode lengths L2 of the source electrodes 32 and the drain electrodes 34 of the FETs 12 through 14.

In the aforementioned first embodiment, each of the FETs 11 through 15 and 21 through 25 that form the switches 10 and 20 has a multiple-gate structure in which multiple unit FETs each having one gate electrode, one source electrode and one drain electrode are connected in parallel. The total electrode length of the source electrode 33 and the drain electrode 35 of at least one of the unit FETs in each of the FETs 11 and 15 may be set smaller than the total electrode length of the source electrode 32 and the drain electrode 34 in each of the FETs 11 through 14. It is thus possible to secure the linearity in the ON state and restrain the cutoff characteristic in the OFF state from being degraded. In order to obtain these effects more greatly, preferably, the all of the electrode lengths L of the source electrodes 33 and the drain electrodes 35 of the FETs 11 and 15 are made smaller than the electrode lengths L2 of the source electrodes 32 and the drain electrodes 34 of the FETs 12 through 14.

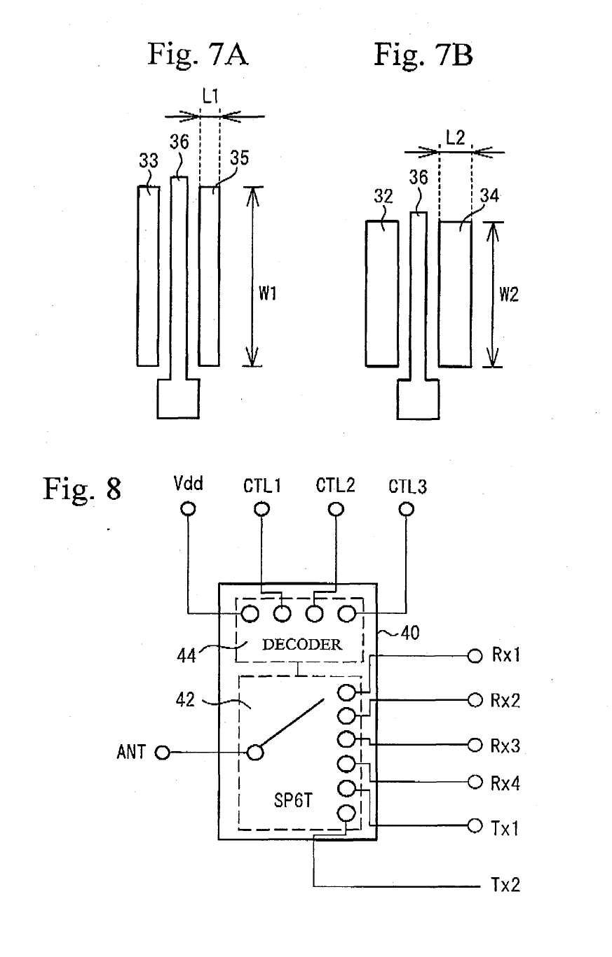

The FETs 11 and 15 and 12 through 14 may have a single-finger structure as shown in FIGS. 7A and 7B, in which the gate electrode 36 is interposed between the source electrode 33 and the drain electrode 35 (FIG. 7A) and between the source electrode 32 and the drain electrode 34 (FIG. 7B).

In the first embodiment, the gate widths of the FETs 11 and 15 are made greater than those of the FETs 12 through 14 by setting the gate width W1 per finger in the FETs 11 and 15 greater than the gate width W2 per finger in the FETs 12 through 14. Widening of the gates of the FETs 11 and 15 may be achieved by setting the number of electrode fingers of the FETs 11 and 15 greater than the number of electrode fingers of the FETs 12 through 14.

In the structure shown in FIG. 1 having the switches 10 and 20, only the FETs 11 and 21 via which the switches 10 and 20 are commonly connected to the antennal terminal ANT (common terminal) may be the first FETs having the increased gate widths W1 and the reduced electrode lengths L1. The cutoff characteristics of the first switches 10 and 20 can be secured when the high-frequency signal is applied to the antenna terminal ANT.

### SECOND EMBODIMENT

FIG. 8 shows a switch circuit 40 in accordance with a second embodiment. The switch circuit 40 has a decoder 44 and an SP6T (Single Pole 6 Throw) 42, and selectively connects the antenna terminal ANT to any one of reception terminals Rx1 through Rx4 and transmission terminals Tx1 and Tx2.

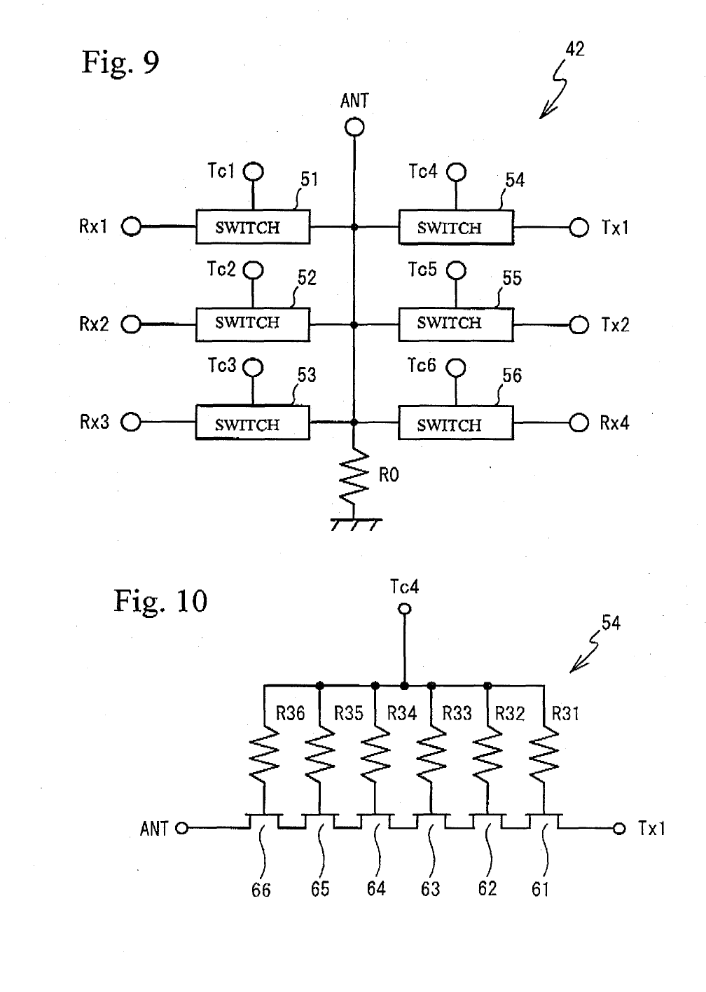

FIG. 9 is a block diagram of the SP6T 42, which includes switches 51 through 56. The switches 51 through 53 and 56 are connected between the antenna terminal ANT and the reception terminals Rx1 through Rx4, respectively, and the switches 54 and 55 are connected between the antenna terminal ANT and the transmission terminals Tx1 and Tx2. Control signal from the decoder 44 are applied to control terminals Tc1 through Tc6 of the switches 51 through 56.

FIG. 10 is a circuit diagram of the switch 54. A plurality of FETs 61 through 66 are connected in series between the transmission terminal Tx1 and the antenna terminal ANT. The gates of the FETS 61 through 66 are connected to the control terminal Tc4 via resistors R31 through R36, respectively. The FETs 61 through 66 perform a switching operation in accordance with the control signal applied to the control terminal Tc4. Similarly, each of the switches 51 through 53, 55 and 56 is composed of multiple FETs.

The decoder 44 shown in FIG. 8 outputs control signals to the control terminals Tc1 through Tc6 shown in FIG. 9 on the basis of signals applied to control terminals CTL1 through CTL3 from the decoder 44. Thus, any of the reception terminals Rx1 through Rx4 and the transmission terminals Tx1 and Tx2 may be selectively connected to the antenna terminal ANT.

Referring to FIG. 10, the high-frequency signal is applied to the transmission terminal Tx1. Thus, the FET 61 of the switch 54 closest to the transmission terminal Tx1 is designed to have the same electrode length L1 and the gate width W1 as those of the FETs 11 and 15 of the first embodiment, and the remaining FETs 62 through 66 are designed to have the same electrode lengths L2 and the gate widths W2 as those of the FETs 12 through 14. It is thus possible to enlarge the linear range of the drain current vs. drain voltage of the FET 61 closest to the transmission terminal Tx1 to which the greatest RF power is applied and to thus improve the distortion characteristic. Further, the cutoff characteristic in the OFF state can be improved.

According to the second embodiment, at least one of the switches 51 through 56 connected to the antenna terminal ANT (common terminal) and composed of FETs may be designed so that the electrode length of the FET 61 of the initial stage can be made smaller than the electrode lengths of the FETs 62 through 64 of the intermediate stages. In the switch circuit in which multiple switches are connected to the antenna terminal ANT, signal leakage via the switch that is in the OFF state can be restrained if the switch circuit has a good cutoff characteristic in the OFF state. It is thus possible to restrain signal distortion (non-linearity) caused by the switch that is in the ON state. The second embodiment is capable of more effectively restraining degradation of the cutoff characteristic in the OFF state of each switch.

The FETs employed in the first and second embodiments are HEMTs, but may be FETs made of Si (silicon) or GaAs (gallium arsenide) having a bulk channel.

The present invention is not limited to the specifically disclosed embodiments, but may include other embodiments and variations without departing from the scope of the present invention.

What is claimed is:

1. A semiconductor device having a switch comprising:
a terminal;
another terminal;
a first FET connected to the terminal; and
a second FET of a stage following that of the first FET,
a gate width of the first FET being greater than that of the second FET,
a sum of lengths of a source electrode and a drain electrode of the first FET in a direction perpendicular to the gate width of the first FET being smaller than a sum of lengths of a source electrode and a drain electrode of the second FET in a direction perpendicular to the gate width of the second FET.

2. The semiconductor device as claimed in claim 1, wherein the lengths of the source electrode and the drain electrode of the first FET in the direction perpendicular to the gate width of the first FET are respectively smaller than those of the source electrode and the drain electrode of the second FET in the direction perpendicular to the gate width of the second FET.

3. The semiconductor device as claimed in claim 1, further comprising an another first FET which has a same structure as that of the first FET, wherein the another first FET is connected between the second FET and the another terminal.

4. The semiconductor device as claimed in claim 1, wherein:
each of the first and second FETs has multiple unit FETs each having one gate electrode, one source electrode and one drain electrode; and
in at least one of the unit FETs of the first FET, the sum of lengths of the source electrode and the drain electrode in the direction perpendicular to the gate width is smaller than the sum of the lengths of the unit FET of the source electrode and the drain electrode of the second FET in the direction perpendicular to the gate width of the second FET.

5. A semiconductor device comprising:
switches connected to a common terminal,
east one of the switches including;
a first FET connected to a terminal; and
a second FET of a stage following that of the first FET,
gate width of the first FET being greater than that of the second FET,
a sum of lengths of a source electrode and a drain electrode of the first FET in a direction perpendicular to the gate width of the first FET being smaller than a sum of lengths of a source electrode and a drain electrode of the second FET in a direction perpendicular to the gate width of the second FET.
